(19) United States
(12) Patent Application Publication
(10) Pub. No.: US 2006/0170442 A1
(43) Pub. Date: Aug. 3, 2006

(54) Protection devices for integrated circuit boards

(75) Inventor: Bing Li, Shenzhen (CN)

Correspondence Address: MORRIS MANNING & MARTIN LLP, 1600 ATLANTA FINANCIAL CENTER, 3343 PEACHTREE ROAD, NE, ATLANTA, GA, 30326-1044, US

(73) Assignee: HON HAI Precision Industry CO., LTD., Tu-Cheng City (TW)

(21) Appl. No.: 11/238,484

(22) Filed: Sep. 28, 2005

(30) Foreign Application Priority Data
Jan. 28, 2005 (CN) 200520054456.2

(51) Int. Cl. G01R 31/02

(52) U.S. Cl. 324/761

(57) ABSTRACT

A protection device for protecting an integrated circuit board (30) includes an upper cover (10) and a lower cover (20). The lower cover includes a body portion (22), a pair of end portions (24) and an edge portion (26) interconnecting the end portions. The body portion, the pair of end portions and the edge portion cooperatively surround a receiving space (28) for receiving the integrated circuit board. A step (262) is formed where the body portion adjoins the end portions and the edge portion. The integrated circuit board is sandwiched between the lower cover and the cover during testing, so that the integrated circuit board is prevented from damage.

### BACKGROUND

1. Field of the Invention

The present invention pertains to physical protection devices for electronic apparatuses, and particularly to protection devices for integrated circuit boards.

2. General Background

Computers, routers and switches commonly utilize a plurality of integrated circuit boards for performing different functions. In mass production, the integrated circuit boards are generally required to undergo different tests in order to determine whether the integrated circuit boards meet standard requirements. During a testing process, the integrated circuit boards have to be frequently inserted into or pulled out from slots of testing apparatuses.

Generally, an integrated circuit board is manually inserted into or pulled out by an operator from a slot of a testing apparatus. During the testing process, the bare integrated circuit board is liable to be contaminated by sweat or dirt of the operator's hands. Furthermore, electronic elements such as integrated circuits, resistors, capacitors, and so on, are liable to be peeled off from the integrated circuit board. One way or another, the bare integrated circuit board may be accidentally damaged. This may lead to malfunction of the computer or router or switch employing such integrated circuit board.

What is needed is a protection device for protecting an integrated circuit board during a testing process.

### SUMMARY

A protection device of the present invention is provided for protecting an integrated circuit board. The protection device comprises an upper cover, and a lower cover. The lower cover comprises a body portion, a pair of end portions, and an edge portion. The body portion, the end portions and the edge portion cooperatively surround a receiving space for receiving the integrated circuit board. A step is formed where the body portion adjoins the second and edge portions. In one embodiment, the body portion defines a recess. A plurality of posts protrudes from the recess. The integrated circuit board is sandwiched between the lower cover and the cover during testing, so that the integrated circuit board is protected from damage.

Other advantages and novel features will become more apparent from the following detailed description when taken in conjunction with the accompanying drawings, in which:

### BRIEF DESCRIPTION OF THE DRAWINGS

FIG. 1 is a exploded, isometric view of a protection device for an integrated circuit board in accordance with a first preferred embodiment of the present invention, together with an integrated circuit board;

FIG. 2 is an isometric view of a cover of the protection device of FIG. 1, but viewed from another aspect;

FIG. 3 is an assembled view of FIG. 1;

FIG. 4 is a exploded, isometric view of a protection device for an integrated circuit board in accordance with a second preferred embodiment of the present invention, together with an integrated circuit board;

FIG. 5 is an isometric view of a cover of the protection device of FIG. 4, but viewed from another aspect; and

FIG. 6 is an assembled view of FIG. 4.

### DETAILED DESCRIPTION OF THE EMBODIMENTS

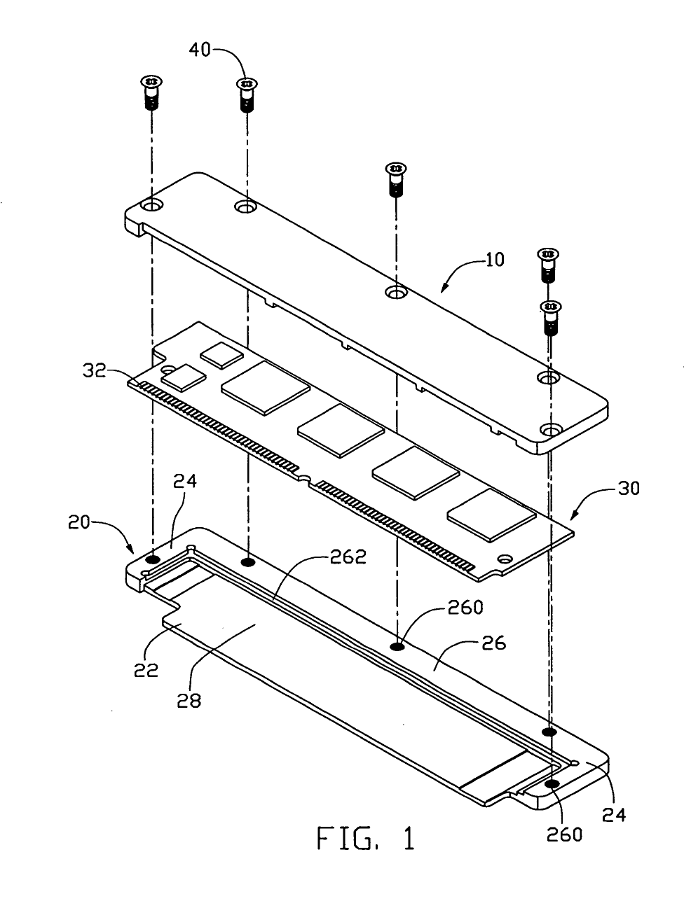

Referring to FIG. 1, a protection device in accordance with a first preferred embodiment of the present invention is used for protecting an electronic member like an integrated circuit board 30 during a testing process. The protection device comprises an upper cover 10, and a lower cover 20.

The integrated circuit board 30 includes a rectangular printed circuit board. A lot of electronic elements are mounted on top and bottom surfaces of the integrated circuit board 30, such as integrated circuits, resistors, capacitors, and so on. A plurality of connecting fingers 32 is located at an edge portion of the integrated circuit board 30.

The lower cover 20 comprises a body portion 22, two opposite end portions 24, and an edge portion 26. The edge portion 26 interconnects the end portions 24. The body portion 22, the end portions 24 and the second edge portion 26 cooperatively bound a receiving space 28 for receiving the integrated circuit board 30. Note that, in an alternative embodiment of the present invention, the receiving space 28 can be defined in the upper cover 10 instead. In another alternative embodiment, the upper cover 10 and the lower cover 20 may cooperatively define the receiving space 28 therein. A length of each of the end portions 24 is smaller than a width of the body portion 22, and is smaller than a width of the integrated circuit board 30. The end portions 24 each define a first mounting hole 260. The edge portion 26 defines three first mounting holes 260. A step 262 is formed where the body portion 22 adjoins the end portions 24 and the second edge portion 26. The step 262 is for supporting and retaining the printed circuit board of the integrated circuit board 30. A height of the step 262 above the body portion 22 is generally equal to the maximum height of corresponding electronic elements on the integrated circuit board 30. A height from the step 262 to tops of the end portions 24 and edge portion 26 is substantially equal to a thickness of the printed circuit board of the integrated circuit board 30.

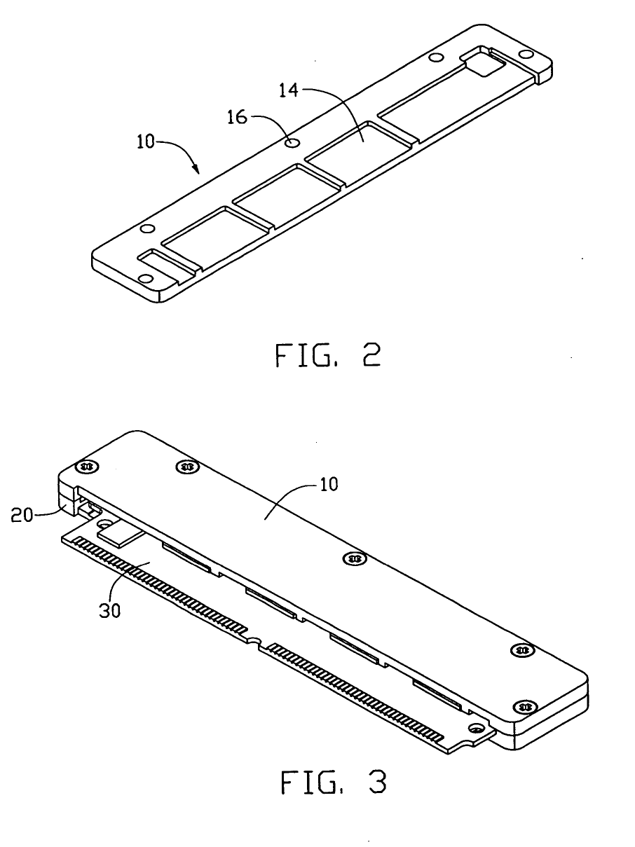

Referring also to FIG. 2, a plurality of receiving holes 14 are defined in an inside of the upper cover 10. A depth of the receiving holes 14 is substantially equal to a maximum height of corresponding electronic elements on the integrated circuit board 30. The number of receiving holes 14 is configured according to the number of integrated circuits on the integrated circuit board 30. The upper cover 10 has five second mounting holes 16, corresponding to the first mounting holes 260 of the lower cover 20 respectively.

Referring to FIGS. 1 and 3, in assembly, the integrated circuit board 30 is received in the lower cover 20, and the upper cover 10 is mounted on the lower cover 20. Five fasteners, for example screw bolts 40, are inserted through the second mounting holes 16 of the upper cover 10 and threadingly engaged with the first mounting holes 260 of the lower cover 20. Thus, the upper cover 10, the lower cover 20 and the integrated circuit board 30 are assembled together.

Because the integrated circuit board 30 is sandwiched between the upper cover 10 and the lower cover 20, the integrated circuit board 30 is prevented from contamination by sweat or dirt of an operator's hands. The electronic elements of the integrated circuit board 30 are protected from accidental damage, even if they undergo repeated testing, i.e., satisfactory quality of the integrated circuit board 30 is maintained.

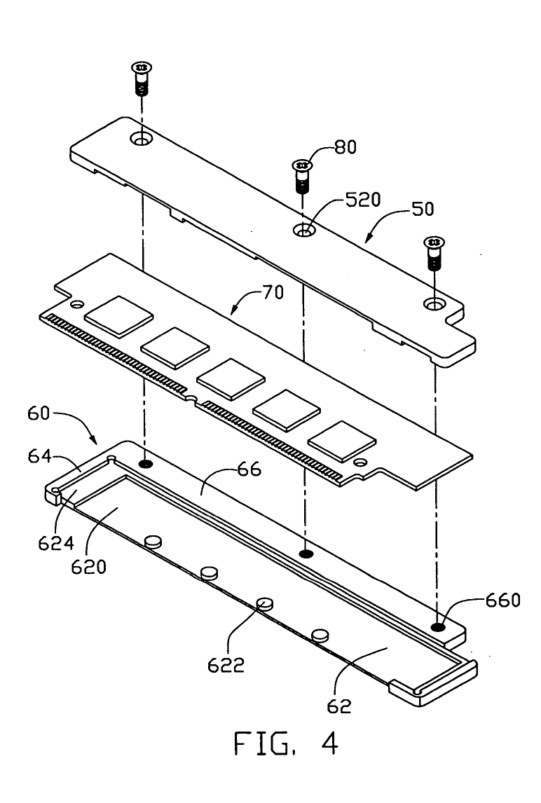

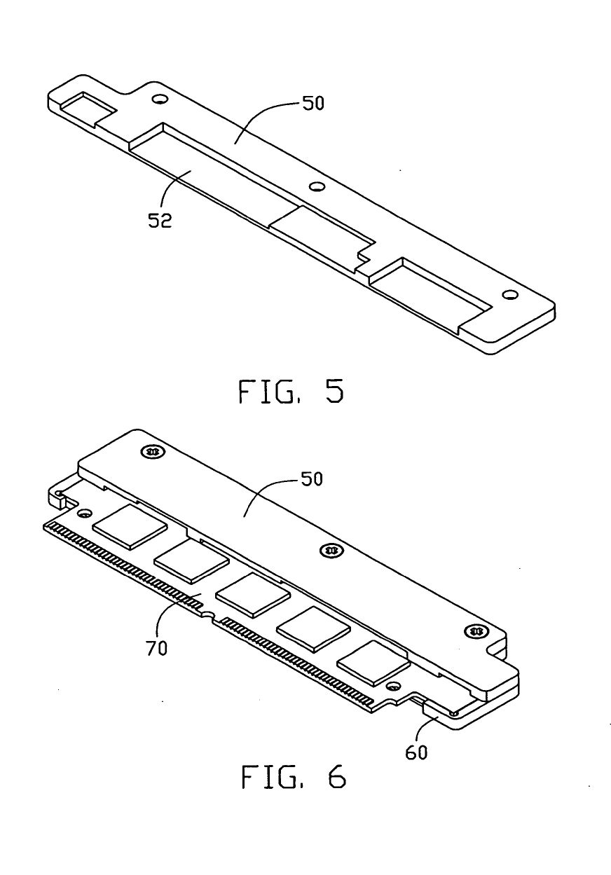

Referring to FIGS. 4-6, a protection device in accordance with a second preferred embodiment of the present invention is used for protecting an integrated circuit board 70 during a testing process. The protection device comprises an upper cover 50 and a lower cover 60. The integrated circuit board 70 has a structure similar to that of the integrated circuit board 30 described in relation to the first preferred embodiment.

The lower cover 60 has a structure similar to that of the lower cover 20 of the first preferred embodiment. The lower cover 60 comprises a body portion 62, two opposite end portions 64, and an edge portion 66. The edge portion 66 defines three first mounting holes 660. A recess 620 is defined in the body portion 62, whereby a step 624 is formed where the body portion 62 adjoins the end portions 64 and edge portion 66. A plurality of protrusions 622 extends upwardly from the recess 620 of the body portion 62, for supporting the integrated circuit board 70. A height of the protrusions 622 is equal to that of the step 624.

The upper cover 50 has a structure similar to that of the upper cover 10 of the first preferred embodiment. The upper cover 50 defines a plurality of receiving holes 52, and three second mounting holes 520 corresponding to the first mounting holes 660 of the lower cover 60. The number of receiving holes 52 is configured according to the integrated circuit board 70. Three fasteners, for example screw bolts 80, are extended through the second mounting holes 520 and threadingly engaged in the first mounting hole 660 of the lower cover 60. The integrated circuit board 70 is thereby sandwiched between the upper cover 50 and the lower cover 60. The upper cover 50 and the lower cover 60 have characteristics and perform functions similar to those of the upper cover 50 and the lower cover 60 of the first preferred embodiment.

While various embodiments have been described above, it should be understood that they have been presented by way of example only and not by way of limitation. Thus the breadth and scope of the present invention should not be limited by the above-described exemplary embodiments, but should be defined only in accordance with the following claims and their equivalents.

I claim:

1. A protection device for an integrated circuit board having a printed circuit board with a plurality of integrated circuits mounted thereon, the protection device comprising:
an upper cover; and
a lower cover detachably coupled to the upper cover; wherein
at least one of the upper cover and lower cover comprises a retaining portion for retaining the printed circuit board in position, and at least one of the upper cover and lower cover defines a receiving space therein for receiving at least one portion or portions of the integrated circuit board therein.

2. The protection device as claimed in claim 1, wherein the retaining portion comprises a step formed on at least one of the upper cover and lower cover.

3. The protection device as claimed in claim 1, wherein the receiving space comprises a plurality of partitioned recesses for receiving corresponding integrated circuits of the integrated circuit board therein.

4. The protection device as claimed in claim 1, wherein the receiving space comprises a space for receiving the printed circuit board of the integrated circuit board.

5. The protection device as claimed in claim 4, wherein at least one protrusion extends from a surface of the at least one of the upper cover and lower cover in the receiving space, for supporting the printed circuit board of the integrated circuit board.

6. The protection device as claimed in claim 1, wherein the upper cover and the lower cover are coupled to each other by at least one fastener.

7. A protection device of an integrated circuit board, comprising:
an upper cover;
a lower cover coupled to the upper cover, the lower cover comprising a body portion, two opposite end portions and an edge portion interconnecting the end portions, a plurality of posts extending from the body portion for supporting the integrated circuit board; and
a receiving space for receiving the integrated circuit board, the receiving space being defined in at least one of the upper cover and the lower cover.

8. The protection device as claimed in claim 7, wherein the body portion, the end portions and the edge portion cooperatively bound a part of the receiving space.

9. The protection device as claimed in claim 7, wherein the body portion comprises at least one recess.

10. The protection device as claimed in claim 9, wherein the posts extend from the recess.

11. The protection device as claimed in claim 7, wherein the lower cover defines a plurality of first mounting holes, and the cover defines a plurality of corresponding second mounting holes.

12. An assembly comprising:
an electronic member comprising a portion for further electrical connection, and another portion having electronic elements exposably mounted thereon;
a protection device enclosing said another portion of said electronic member to provide at least one touchable and force-endurable surface outside said another portion of said electronic member, and said at least one surface shieldingly covering said electronic elements mounted on said another portion of said electronic member so as to avoid exposedness of said electronic elements.

13. The assembly as claimed in claim 12, wherein said protection device comprises an upper cover and a lower cover to respectively shieldingly covering at least two different sides of said another portion of said electronic member.

14. The assembly as claimed in claim 12, wherein said protection device forms one of a step and a protrusion extending therefrom toward said another portion of said electronic member for better abutment between said protection device and said another portion of said electronic member.
